(19) United States
(12) Patent Application Publication
(10) Pub. No.: US 2010/0117072 A1
(43) Pub. Date: May 13, 2010

(54) LIGHT EMITTING APPARATUS AND METHOD OF MANUFACTURING THE SAME

(75) Inventors: Masato Ofuji, Kawasaki-shi (JP); Katsumi Abe, Kawasaki-shi (JP); Ryo Hayashi, Yokohama-shi (JP); Masafumi Sano, Yokohama-shi (JP); Hideya Kumomi, Tokyo (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/596,998

(22) PCT Filed: Apr. 23, 2008
(86) PCT No.: PCT/JP2008/058296

§ 371 Date: Oct. 22, 2009

(30) Foreign Application Priority Data
Apr. 27, 2007 (JP) 2007-118737

(51) Int. Cl. H01L 33/00; H01L 29/04; H01L 21/00; H01L 21/84

(52) U.S. Cl. 257/43; 257/59; 438/29; 438/158; 257/E29.296; 257/E33.019; 257/E21.411

(57) ABSTRACT

To provide a light emitting apparatus in which high definition can be realized and the connection reliability of a wiring portion is excellent, the light emitting apparatus includes: a substrate; a light emitting element which includes a first electrode, an emission layer, and a second electrode which are stacked on the substrate in the stated order; and a thin film transistor which is of an n-type and includes a channel layer and a drain electrode, the light emitting element and the thin film transistor are arranged in parallel and in contact with the substrate, the channel layer of the thin film transistor has a field effect mobility equal to or larger than 1 cm²V⁻¹s⁻¹, and the second electrode is connected with the drain electrode of the thin film transistor.

### TECHNICAL FIELD

The present invention relates to a light emitting apparatus including a light emitting element and a method of manufacturing the light emitting apparatus, and more particularly, to a light emitting apparatus including an organic light emitting diode (OLED) and a method of manufacturing the light emitting apparatus.

### BACKGROUND ART

In recent years, active research on a light emitting apparatus using organic light emitting diodes (OLEDs) has been conducted. The light emitting apparatus using the OLED has excellent features such as self emission, a high-speed response, and a wide viewing angle and is expected for applications to a large-screen and high-definition display apparatus. A normal OLED has a structure in which an anode, an organic layer, and a cathode are stacked on a substrate made of, for example, glass in the stated order.

The OLED deteriorates with a driving time to increase an inter-terminal resistance. The deterioration becomes significant as a driving current increases. Therefore, in order to enable small-current driving while luminance required to realize a display apparatus is maintained, it is essential to perform the frame holding operation of each pixel and it is important to employ an active matrix driving technology.

Thin film transistors (TFTs) using various channel materials are disclosed as active matrix driving elements for driving the OLEDs. For example, there are amorphous silicon TFTs (see US Patent Application Publication No. 2005/212418), low-temperature polycrystalline silicon TFTs, and organic TFTs (see Japanese Patent Application Laid-Open No. 2003-255857).

In order to stably control the OLED even when the deterioration proceeds, in the case of a p-type TFT for driving, it is desirable to connect the anode of the OLED with the drain electrode of the TFT. When an n-type TFT is used, it is desirable to connect the cathode of the OLED with the drain electrode of the TFT. When the p-type TFT is used, the integration is easier. This reason is as follows. The anode of the OLED is formed on a lower surface side of the element and the cathode thereof is formed on an upper surface side thereof, so a wiring layer for connecting the drain electrode of the TFT with the cathode of the OLED can be directly formed on the substrate as described in Japanese Patent Application Laid-Open No. 2003-255857.

However, the low-temperature polycrystalline silicon TFT serving as the p-type TFT has a problem that a manufacturing process is complicated, a manufacturing cost is high, and it is difficult to realize a large-area display. Many organic TFTs are p-type, but electrical characteristics and environmental stability thereof are practically insufficient.

The amorphous silicon TFT is n-type. The TFT can be manufactured at low cost, is widely used for liquid crystal display apparatuses, and is under active development aiming to drive the OLEDs. When the cathode of the OLED is to be connected with the drain electrode of the n-type TFT, it is necessary to extend a wiring beyond at least a thickness of the emission layer of the OLED.

In recent years, a TFT using a transparent conductive oxide polycrystalline thin film for not only a transparent electrode but also a channel layer has been under active development. For example, a TFT using a transparent conductive oxide polycrystalline thin film containing ZnO as a main ingredient for a channel layer is disclosed in U.S. Pat. No. 7,061,014. The following is described in Japanese Patent Application Laid-Open No. 2000-044236. That is, an amorphous oxide film is used for a transparent electrode. The amorphous oxide film is made of ZnₓM_{y}In_{z}O_{(x+3y/2+3z/2)} (in which M indicates at least one element of Al and Ga, a ratio x/y is in a range of 0.2 to 12, and a ratio z/y is in a range of 0.4 to 1.4). Each of the thin films exhibits an n-type conductivity. The field effect mobility of the TFT using the thin films exceeds the field effect mobility of the amorphous silicon TFT. The thin film can be formed at low temperature and is transparent to visible light. Therefore, it is said that a flexible transparent TFT can be formed on a substrate such as a plastic plate or film. A potential example of a method of forming the flexible transparent TFT is a sputtering method capable of forming a uniform thin film over a large area.

As an example of a method of connecting the OLED with the n-type TFT, a method of stacking the TFT and the OLED in a substrate thickness direction using a planarization layer is disclosed in US Patent Application Publication No. 2005/212418. In this case, light from the OLED is emitted to a direction away from the TFT (top emission type). In US Patent Application Publication No. 2005/212418, the cathode of the OLED is connected with a source electrode of the TFT at a position beyond a total thickness of a buffer layer and the planarization layer of a TFT substrate.

According to the method in US Patent Application Publication No. 2005/212418, the buffer layer is formed to separate organic layers for respective pixels and has a larger thickness than the organic layer. In many cases, the thickness of the buffer layer is 100 nm to several μm. In particular, when the emission layer is to be made from a solution, a large amount of solution is temporarily put on the substrate. Therefore, in order to form different emission layers between adjacent pixels without mixing, it is necessary to thicken the buffer layer (normal thickness equal to or larger than 1 μm). The planarization layer is literally used to absorb the unevenness of the substrate, which is caused by the thickness of the TFT, and has a thickness of at least approximately 1 μm.

When the cathode of the light emitting element is to be connected with the drain electrode of the TFT, a wiring layer extends beyond a height difference of approximately 1.5 μm to several μm. In some cases, a step cannot be sufficiently covered with the wiring layer extending beyond the large height difference. In such cases, fault connection (disconnection at step) occurs. When each of the planarization layer and the buffer layer is to be formed, a photolithography process is necessary, thereby increasing a manufacturing cost. In particular, when each of the planarization layer and the buffer layer is thick, a process time becomes longer.

A method of arranging the OLED and the n-type TFT in parallel is expected as the simplest method of connecting the OLED with the n-type TFT. However, when the amorphous silicon TFT is used as the n-type TFT in this method, a layout area of the TFT becomes very large because of small field effect mobility. Therefore, it is very difficult to realize high-definition pixel.

That is, when a normal light emitting apparatus is to be designed in which the OLED is driven by the n-type TFT, connection reliability and high definition are incompatible demands. Therefore, it is necessary to satisfy both demands.

### DISCLOSURE OF THE INVENTION

The present invention has been made to solve the problems. An object of the present invention is to provide a light emitting apparatus in which high definition can be realized and the connection reliability of a wiring portion is excellent.

A light emitting apparatus according to the present invention includes: a substrate; a light emitting element which includes a first electrode, an emission layer, and a second electrode which are stacked on the substrate in the stated order; and a thin film transistor which is of n-type and includes a channel layer and a drain electrode, the light emitting element and the thin film transistor are arranged in parallel and in contact with the substrate, the channel layer of the thin film transistor has a field effect mobility equal to or larger than 1 cm²V⁻¹s⁻¹, and the second electrode is connected with the drain electrode of the thin film transistor. Further, the channel layer of the thin film transistor contains at least one element selected from the group consisting of In, Ga, and Zn, and at least a part of the channel layer includes an amorphous oxide. Further, the emission layer includes an organic compound. Further, at least one of the first electrode and the second electrode includes a transparent conductive oxide. The light emitting apparatus further includes an insulator inserted between the substrate and the first electrode. Further, the insulator includes a channel protecting layer. Further, the insulator includes a planarization layer for the first electrode. The light emitting apparatus further includes a bank provided between pixels located adjacent to each other, for separating the emission layers. Further, at least a part of a channel portion of the thin film transistor is formed in the bank. The light emitting apparatus further includes a channel protecting layer, and the channel protecting layer acts as the bank.

The present invention also provides a method of manufacturing a light emitting apparatus, including: forming, on a substrate, a thin film transistor which is of n-type and includes a gate electrode, a line, a gate insulator, a channel layer, a source electrode, a drain electrode, and a channel protecting layer; forming, on the substrate, a first electrode of a light emitting element in parallel with the thin film transistor; stacking an emission layer on the first electrode; stacking a second electrode on the emission layer and the drain electrode of the thin film transistor to connect the emission layer with the drain electrode; and sealing a portion including at least the light emitting element on the substrate on which the light emitting element and the thin film transistor are formed, in which the stacking the emission layer on the first electrode is performed so as not to form the emission layer on at least a part of a surface of the drain electrode of the thin film transistor. The method further includes performing hydrophobic treatment on at least the part of the surface of the drain electrode before the stacking the emission layer on the first electrode. Further, the hydrophobic treatment includes chemical modification treatment with partially fluorinated alkanethiol, which is performed on the surface of the drain electrode. The method further includes: after the stacking the emission layer on the first electrode, removing a part of the emission layer formed on the drain electrode. Further, the removing the part of the emission layer includes treatment using laser ablation.

According to the present invention, the OLED and the n-type TFT, placed in parallel with each other, are connected with each other, and the oxide semiconductor is used for the channel layer. Therefore, it is possible to manufacture a light emitting apparatus with high definition and high connection yield. According to the present invention, a light emitting apparatus using the organic material for the emission layer can be provided at low cost. According to the present invention, a light emitting apparatus that is compatible with large-area fabrication can be provided. Further, according to the present invention, a light emitting apparatus of a bottom emission type, a top emission type, and a both-surface emission type can be provided. Further, according to the present invention, it is possible to provide a light emitting apparatus using one of a substrate which is light and resistant to breaking, such as a plastic substrate, and a flexible substrate.

Further features of the present invention will become apparent from the following description of exemplary embodiments with reference to the attached drawings.

### BRIEF DESCRIPTION OF THE DRAWINGS

FIG. 1 is an explanatory cross sectional view illustrating a light emitting apparatus according to a fundamental embodiment of the present invention.

FIGS. 2A, 2B, 2C, 2D, 2E, and 2F are explanatory views illustrating the steps of producing the light emitting apparatus according to the fundamental embodiment of the present invention.

FIG. 3 is an explanatory cross sectional view illustrating a light emitting apparatus according to another embodiment of the present invention.

FIG. 4 is an explanatory cross sectional view illustrating a light emitting apparatus according to another embodiment of the present invention.

FIGS. 5A, 5B, 5C, 5D, 5E, and 5F are explanatory views illustrating the steps of producing a light emitting apparatus according to another embodiment of the present invention.

FIG. 6 is an explanatory cross sectional view illustrating a light emitting apparatus according to another embodiment of the present invention.

FIG. 7 is an explanatory cross sectional view illustrating a light emitting apparatus according to another embodiment of the present invention.

FIG. 8 is a graph illustrating an Ids-Vgs characteristic (solid line) and a √Ids-Vgs characteristic (broken line).

### BEST MODE FOR CARRYING OUT THE INVENTION

First, a light emitting apparatus according to the present invention will be schematically described.

The inventers of the present invention energetically conducted the pursuit of semiconductor materials for the channel layer of a thin film transistor (TFT) and the research on the integration of the TFT and a light emitting element. As a result, the following was found. In the case where a certain type of semiconductor material is used for the channel layer, even when the TFT and the light emitting element are arranged in parallel to easily connect the TFT with the light emitting element, high definition can be realized.

A typical light emitting apparatus is assumed and a current necessary to drive a light emitting element included therein is estimated as follows.

A maximum pixel size of a 60-inch diagonal color full high-definition (1080p) panel is 692×231 (μm²). Assume that a device having the same light emitting area as that of the panel is driven at a maximum luminance of 2000 cdm⁻² in view of the presence of a non-light emission region including lines and a light extraction loss. When light emitting efficiency is 5 cdA⁻¹, a necessary current is 64×10⁻⁶ (A) (=1000×(692×10⁻⁶)×(231×10⁻⁶)/5).

Next, a field effect mobility p required for the TFT driving the light emitting element is calculated.

The driving TFT is operated mainly in a saturation region. Therefore, the current-voltage characteristic of the TFT is expressed by Ids=(½L)WμCi (Vgs−Vth)². Note that W indicates a channel width (μm), L indicates a channel length (μm), μ indicates the field effect mobility (cm²V⁻¹s⁻¹), Ci indicates a capacitance of a gate insulator per unit area (Fcm⁻²), Vgs indicates a gate-source voltage of the driving TFT (V), and Vth indicates a threshold voltage of the driving TFT (V).

When the TFT and the light emitting element are arranged in parallel, the layout area of the TFT becomes tighter because a TFT portion does not emit light. Assume that a maximum channel width W capable of ensuring a necessary aperture ratio in the case where the TFT and the light emitting element are arranged in parallel is 690 (μm), L=5 (μm), Ci=17 nFcm⁻² (200 nm-thick SiO₂), and (Vgs−Vth)=4 (V).

When a maximum value of the field effect mobility of the amorphous silicon TFT in an experimental level is assumed to be 1, a maximum drain current value which is derived from the above-mentioned expression is 19 μA. This calculation is an example. In the case where a TFT whose field effect mobility is approximately 1 is used, when the channel width does not increase, current driving power required for the light emitting element cannot be generated. The field effect mobility of commercial amorphous silicon TFT is further small. Therefore, when amorphous silicon TFT is used, it is very difficult to manufacture the light emitting apparatus in which the light emitting element and the TFT are arranged in parallel.

In contrast to this, when the oxide semiconductor is used for the channel layer, a TFT whose field effect mobility μ is equal to or larger than approximately 5, for example, can be easily manufactured. Therefore, the oxide semiconductor can be suitably used for the driving TFT of the light emitting apparatus as described above in which the light emitting element and the TFT are arranged in parallel.

When the field effect mobility is larger than a necessary minimum limit, there arises another advantage. For example, an actual channel width W can be reduced to a value smaller than 690 (μm). That is, in this case, the aperture ratio can be increased. Therefore, current density in the light emitting element can be reduced. Furthermore, in the case where the light emitting element is the OLED, the deterioration of the OLED can be delayed. Not an increase in aperture ratio but an increase in the number of TFTs used for a pixel circuit may be realized. Therefore, a more advanced function such as canceling the influence of deterioration on the TFT itself can be provided for the pixel circuit.

It is desirable to use a organic light-emitting diode (OLED), where the emission layer is made of organic compounds, as the light emitting element. In such a case, a film formation temperature of each of constituent elements (anode, emission layer, and cathode) is low, so the light emitting element can be manufactured on a flexible substrate such as a plastic substrate.

In order to realize excellent display, it is necessary for at least one of a first electrode and a second electrode which sandwich the emission layer to ensure sufficient light transmittance. When the first electrode located on the substrate side is made substantially transparent, a bottom emission type light emitting apparatus can be manufactured. When the second electrode located on the side opposed to the substrate is made substantially transparent, a top emission type light emitting apparatus can be manufactured. When the transmittance of each of the first electrode and the second electrode is increased, a both-surface emission type light emitting apparatus can be manufactured.

A transparent conductive oxide is suitable as a transparent electrode material satisfying the above-mentioned purposes.

Hereinafter, light emitting apparatuses according to embodiments of the present invention will be described in detail with reference to the attached drawings.

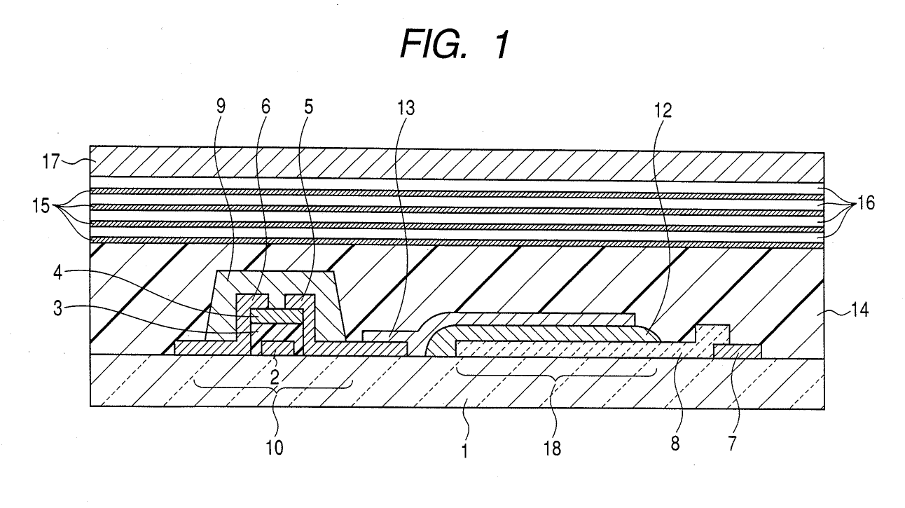

A most fundamental embodiment of the present invention will be described with reference to FIG. 1.

A light emitting apparatuses according to the present invention includes at least a substrate 1, a light emitting element 18, and a TFT 10. The light emitting element 18 and the TFT 10 are formed in contact with the substrate 1. The light emitting element 18 includes a first electrode 8, an emission layer 12, and a second electrode 13, which are stacked from the substrate side in the stated order. The TFT 10 includes a source electrode 6, a drain electrode 5, a gate electrode 2, a gate insulator 3, a channel layer 4, and a channel protecting layer 9.

The channel layer 4 of the TFT 10 is made of an n-type semiconductor. The drain electrode 5 is connected with the second electrode 13 of the light emitting element 18. When the TFT 10 and the light emitting element 18 are seen in projection from above the surface of the substrate 1, the TFT 10 and the light emitting element 18 are arranged in parallel. When the TFT 10 and the light emitting element 18 are seen in projection in a direction perpendicular to the surface of the substrate 1, the bottom surface of the TFT 10 and the bottom surface of the light emitting element 18 are made substantially equal in height to each other to ensure connection reliability. The field effect mobility of the TFT 10 is set to a value larger than 1 cm²V⁻¹s⁻¹ to ensure a necessary aperture ratio.

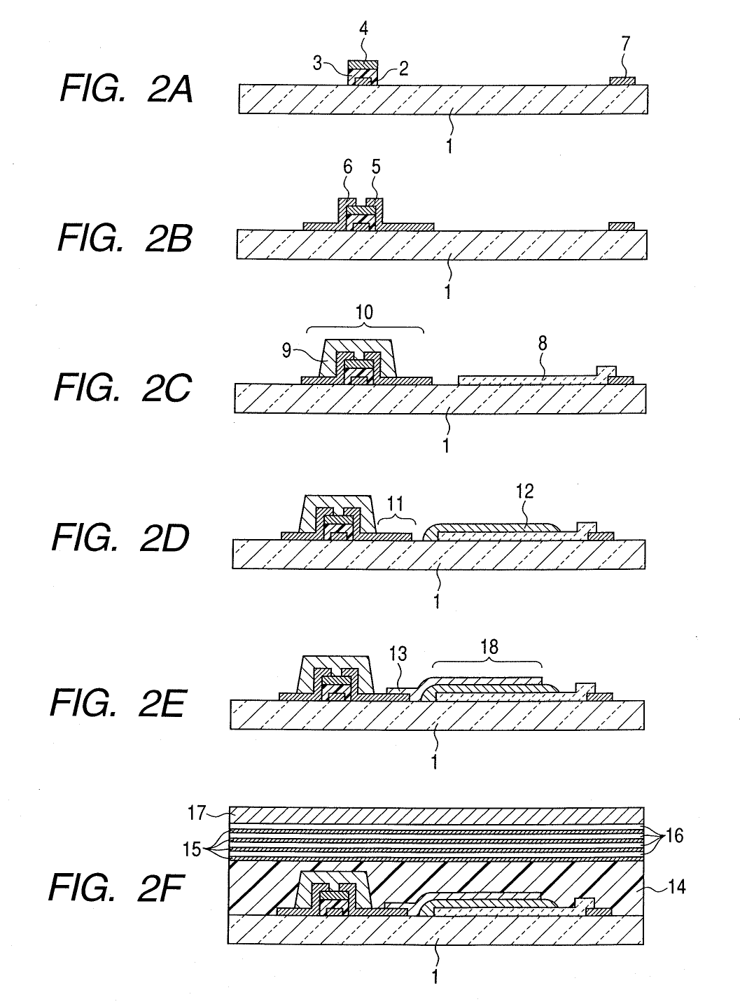

Next, a method of manufacturing the light emitting apparatus according to the most fundamental embodiment of the present invention will be described with reference to FIGS. 2A to 2F.

The TFT 10 is produced in contact with the substrate 1 according to the following procedure. The gate electrode 2 and a line 7 are formed on the substrate 1. Then, the gate insulator 3 and the channel layer 4 are formed. Next, the source electrode 6 and the drain electrode 5 are formed and then the channel protecting layer 9 is formed. The first electrode 8 of the light emitting element is directly formed in contact with the substrate 1. The emission layer 12 of the light emitting element is stacked on the first electrode 8. At the moment before the formation of the second electrode 13, at least a part of the drain electrode 5 of the TFT 10 (exposed part indicated by reference numeral 11 of FIG. 2D) needs to be exposed. In order to expose the exposed part 11, a part of the emission layer 12 is not formed in advance on a predetermined region of the drain electrode 5. Alternatively, the part of the emission layer 12 which is located on the predetermined region is removed after the formation of the emission layer 12. Subsequently, the second electrode 13 is stacked on the emission layer 12. The second electrode 13 extends onto the exposed part 11 of the drain electrode 5 to connect the second electrode 13 with the drain electrode 5. The second electrode 13 may be connected with the drain electrode 5 of the TFT 10 simultaneously with the formation as described above or may be connected therewith through a connection member in another process.

Finally, in order to protect the light emitting element 18 from oxygen and moisture in the atmosphere, a region including at least the light emitting element 18 on the substrate 1 is sealed. This sealing may be performed as follows. For example, as illustrated in FIG. 2F, a light curing resin layer 14, 16 are formed. Inorganic sputtering films 15 and light curing resin layers 16 are alternately stacked on the curing resin layer 14 at an arbitrary cycle. Then, an overcoat layer 17 is formed thereon. Alternatively, the sealing may be performed by capping with a metal can or a glass material.

In this embodiment, the height difference between the bottom surface of the TFT 10 and the bottom surface of the light emitting element 18 can be assumed to be 0. Therefore, the height difference beyond which the second electrode 13 extends is approximately the thickness of the emission layer 12, so a high yield can be expected.

According to another embodiment, the following case may be employed. A part of the substrate 1 on which the first electrode 8 of the light emitting element 18 is to be formed is not exposed and an insulating layer is provided between the substrate and the first electrode on the part of the substrate 1. In this case, the height difference beyond which the wiring extends is approximately a total thickness of the emission layer 12 and the insulating layer. In order to obtain the effect of the present invention, it is necessary to sufficiently reduce the thickness of the insulating layer.

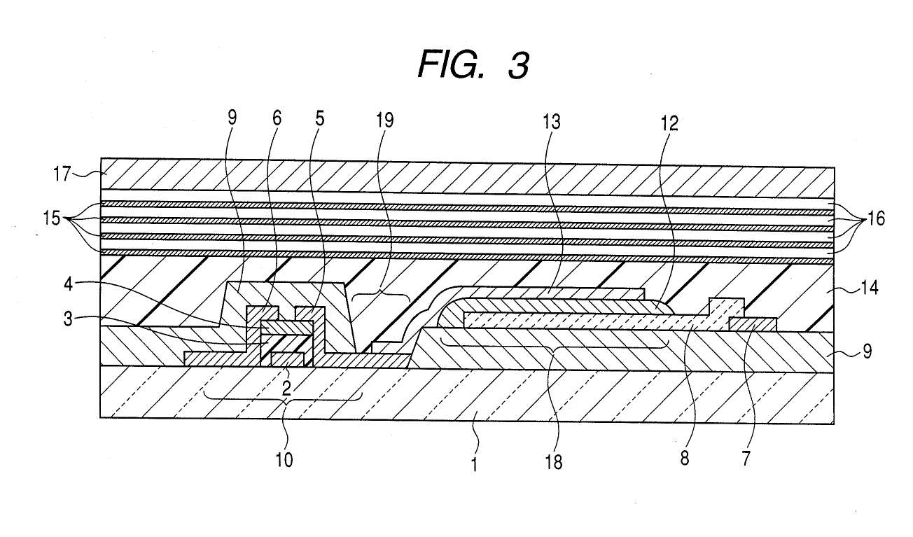

An example of the above-mentioned case includes the case where the channel protecting layer 9 of the TFT 10 is left on the substrate 1 without being etched as illustrated in FIG. 3. In this case, it is necessary to provide a contact hole 19 in a region located above the drain electrode 5 of the TFT 10 and then to expose a part of the drain electrode 5 so as to be able to connect the drain electrode 5 with the second electrode 13 of the light emitting element 18.

In this embodiment, the height difference between the bottom surface of the TFT 10 and the bottom surface of the light emitting element 18 corresponds to the thickness of the channel protecting layer 9. The height difference beyond which the wiring extends is approximately a total thickness of the emission layer 12 and the channel protecting layer 9. As compared with the most fundamental structure described above, the height difference becomes larger. However, the channel protecting layer 9 needs to be thicker than only approximately 400 nm to exhibit sufficient TFT protection performance. Therefore, a high yield can be expected in this embodiment. When the spatial resolution of the patterning of the channel protecting layer 9 is reduced by some reason, the occurrence of faulty devices is more easily avoided in this embodiment as compared with the case of the most fundamental structure described above.

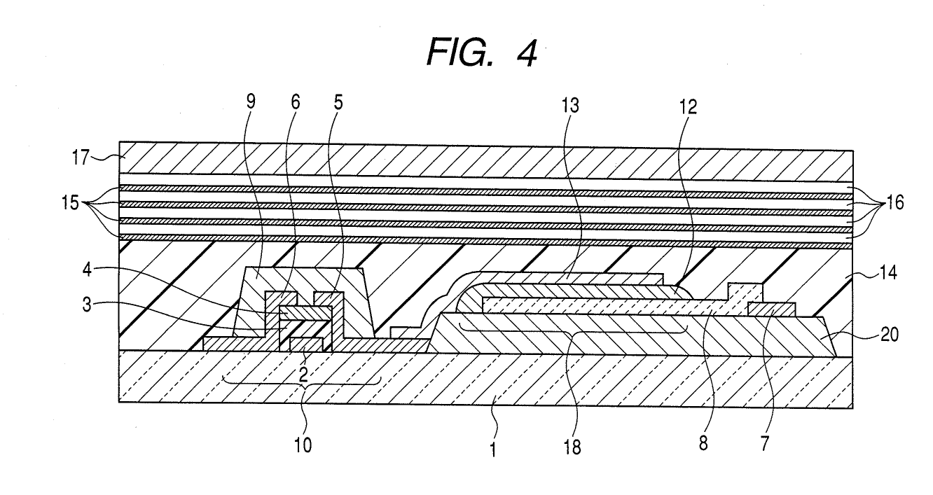

An example of this embodiment includes the case where not the first electrode 8 but a planarization layer 20 for first electrode is provided on a part of the substrate 1 after the TFT 10 is produced as illustrated in FIG. 4. The planarization layer 20 is to absorb only the surface roughness of the substrate 1 over a region corresponding to an area of the first electrode 8. Therefore, the planarization layer 20 can be thinner than a typical planarization layer for interlayer wiring by approximately an order of magnitude or more. Also in this case, at least a part of the drain electrode is exposed as in the above-mentioned case.

In this embodiment, the height difference between the bottom surface of the TFT 10 and the bottom surface of the light emitting element 18 corresponds to the thickness of the planarization layer 20. The height difference beyond which the wiring extends is approximately a total thickness of the emission layer 12 and the planarization layer 20, so a high yield can be expected. According to this embodiment, electric field concentration caused by the unevenness of the first electrode 8 can be avoided to prevent the light emitting element 18 from short circuiting or deteriorating.

An undesirable example which does not correspond to the insulating layer descried above in this embodiment includes a planarization layer for interlayer wiring. The planarization layer for interlayer wiring has a thickness of approximately several μm which is required to absorb a step caused by underlying layers. When a wiring for connecting the light emitting element with the TFT extends beyond the patterned edge of such a layer, the effect of the present invention is not obtained.

Another undesirable example which does not correspond to the insulating layer descried above in this embodiment includes a bank for confining an emission layer solution in the case where the emission layer is formed from solution. The bank has a thickness equal to or larger than at least approximately 1 μm. When the wiring for connecting the light emitting element with the TFT extends beyond the bank, the effect of the present invention is not obtained.

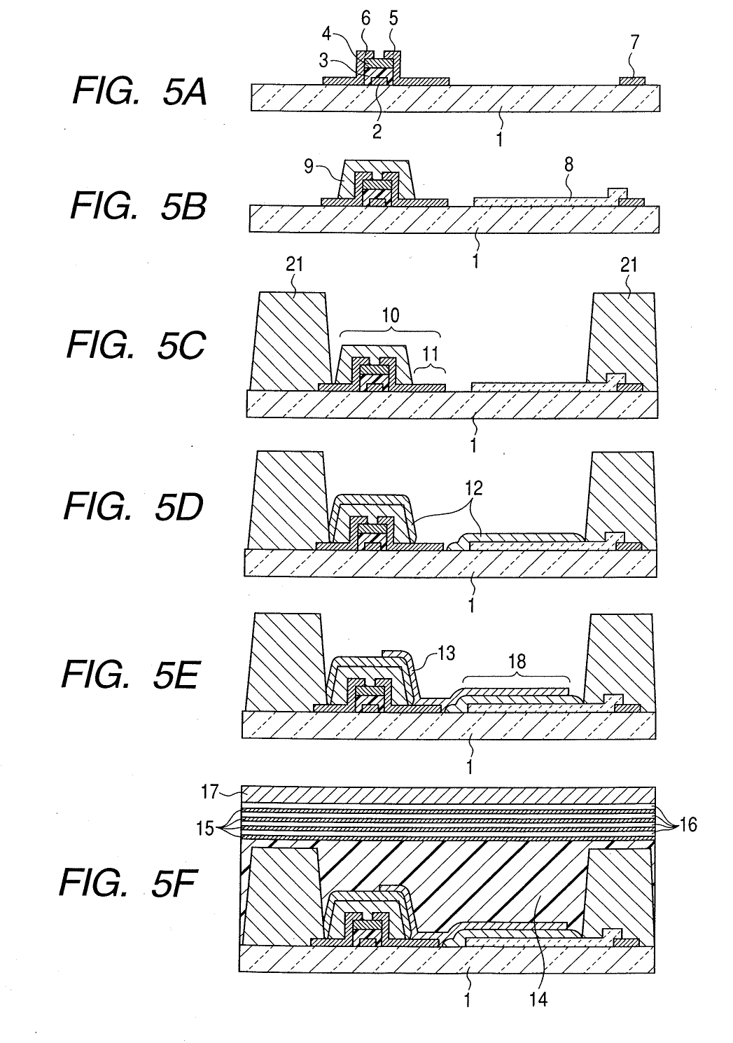

Next, another embodiment of the present invention will be described with reference to FIGS. 5A to 5F. This embodiment is particularly suitable for the case where the emission layer is formed in an application process.

A light emitting apparatus according to this embodiment includes the substrate 1, the light emitting element 18, the TFT 10, and a bank 21 for separating emission layers of adjacent pixels from each other. The light emitting element 18 includes the first electrode 8, the emission layer 12, and the second electrode 13, which are stacked from the substrate side in the stated order. The TFT 10 includes the source electrode 6, the drain electrode 5, the gate electrode 2, the gate insulator 3, the channel layer 4, and the channel protecting layer 9.

A method of manufacturing the light emitting apparatus according to this embodiment will be described with reference to FIGS. 5A to 5F.

The TFT 10 is produced in contact with the substrate 1 according to the same procedure as described above. The first electrode 8 of the light emitting element 18 is directly formed in contact with the substrate 1. The bank 21 is made of, for example, photosensitive polyimide. In order to prevent the emission layer solution from overflowing to adjacent pixels, the bank 21 is sufficiently thickened. In order to expose a part of the drain electrode 5, for example, the exposed part 11 is subjected to chemical modification with partially fluorinated alkanethiol. An organic solvent solution for the emission layer 12 is applied and dried to form the emission layer 12 on the first electrode 8. When the organic solvent solution is dried, at least a portion of the exposed part 11 includes a region in which the emission layer 12 is not formed. Subsequently, the second electrode 13 is stacked on the emission layer 12. At this time, the second electrode 13 extends onto the exposed part 11 to connect the second electrode 13 with the drain electrode 5. Finally, a region including at least the light emitting element 18 on the substrate 1 is sealed.

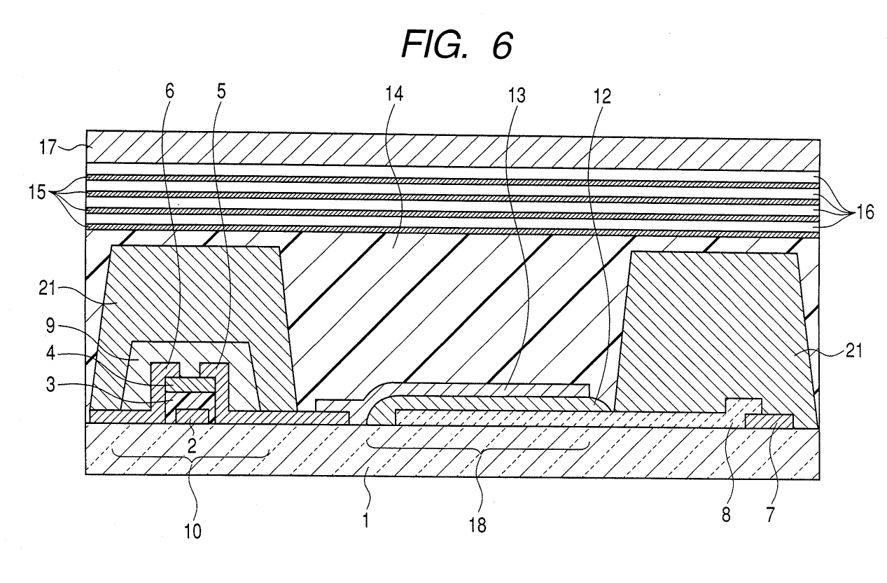

According to this embodiment, the different emission layers 12 for respective pixels can be formed from solution without being mixed with each other. The bank 21 may be provided in parallel to the TFT as described above. As illustrated in FIG. 6, the bank 21 may be provided to cover the channel region of the TFT. In the latter case, it can be expected to improve the aperture ratio.

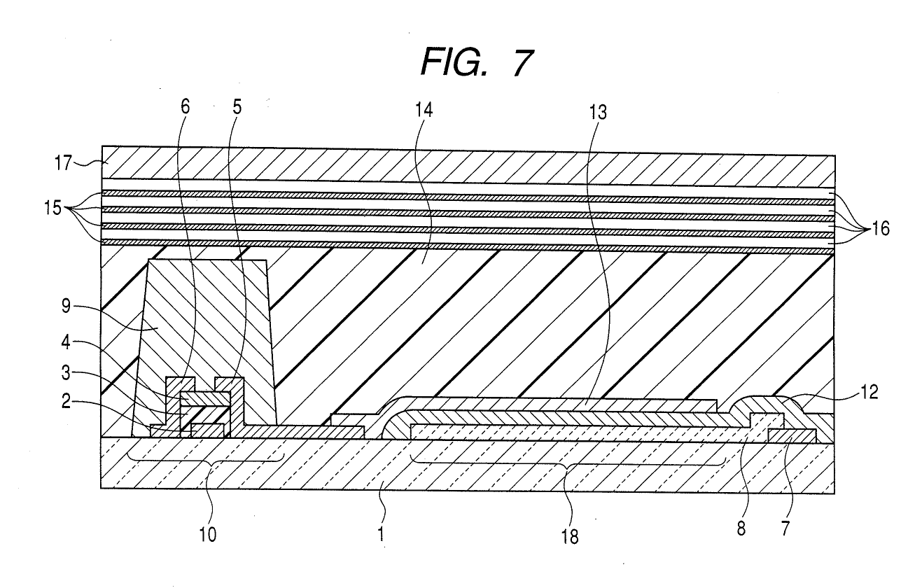

According to another example of this embodiment, as illustrated in FIG. 7, the channel protecting layer for the TFT may be thickened (for example, up to 1 μm in thickness) without providing the bank, to also serve as the bank. Therefore, the structure for separately forming different emission layers for respective pixels from solution can be realized by fewer photolithography steps.

Hereinafter, the respective constituent elements of the light emitting apparatus according to the present invention will be described in more detail.

The substrate will be described.

An insulating material such as glass or plastic is used as a material of the substrate. It is possible to use a semiconductor such as single-crystalline silicon or a conductor such as a metal foil, which is provided with an insulating film as appropriate. When a light emitting element to be integrated is an OLED, in order to suppress the deterioration of the light emitting element and improve a yield thereof, the substrate is required to have sufficient flatness and a sufficient barrier function against moisture and oxygen. When at least one layer for providing the sufficient flatness and the sufficient barrier function is uniformly stacked on the substrate, a substrate including the layer is also referred to as the substrate 1 in view of function.

Next, the light emitting element will be described.

### (a) First Electrode (Lower Electrode)

In order to provide a sufficient hole injection characteristic, a material whose work function is large is used. In addition, sufficient transparency is required for the bottom emission type. When there is a protrusion on an emission layer side surface of the first electrode, electric field concentration occurs thereon to cause the deterioration of the light emitting element. Therefore, the sufficient flatness is required. For example, a tin-doped indium oxide (ITO) film, a gold film, or a platinum film is used.

(b) Emission layer

It is necessary to exhibit a light emitting characteristic required for display. Actually, in order to exhibit an excellent light emitting characteristic, not a single layer but one of multilayer films as described below is suitably used.

(A) Hole transporting layer/emission layer+electron transporting layer (emission layer having electron transport function)
(B) Hole transporting layer/emission layer/electron transporting layer
(C) Hole injecting layer/hole transporting layer/emission layer/electron transporting layer
(D) Hole injecting layer/hole transporting layer/emission layer/electron transporting layer/electron injecting layer
Hereinafter, in this specification, each of the multilayer films is collectively referred to as the emission layer. However, the emission layer in the present invention is not limited to the above-mentioned examples.

A dry process or a wet process is used as a method of forming the emission layer. An example of the dry process includes a vacuum vapor deposition method. Examples of the wet process include squeegee printing, gravure printing, ink-jet application, and dispenser application.

It is necessary for the emission layer to be capable of performing any one of the following treatments (1) and (2).

(1) Because the second electrode 13 of the light emitting element 18 is connected with the drain electrode 5 of the TFT 10 in a subsequent process, the emission layer is patterned by a suitable method so as not to be formed on at least a part of the drain electrode 5.
(2) After the emission layer is uniformly formed, at least a part of the emission layer which is formed on the drain electrode 5 is removed by any method.

In the treatment (1), the emission layer may be prevented in advance from being formed to the exposed part or an opening may be spontaneously formed by a surface energy difference with a base material.

An example of the treatment (1) is masking including a shadow mask vacuum vapor deposition method. According to the shadow mask vacuum vapor deposition method, a substrate contamination risk that may occur in patterning the emission layer is low.

The treatment (2) is effective for the case where the emission layer is formed by particularly an application or printing process. An example of the treatment (2) is that the exposed part of the drain electrode of the TFT is subjected to surface treatment for reducing the surface energy (hydrophobic treatment). When the hydrophobic treatment is performed, an alignment (substrate positioning) process is not necessarily performed. Therefore, selective surface treatment for absorbing base material can be performed, the light emitting apparatus can be manufactured at low cost. To be specific, after the surface of the electrode is chemically modified with partially fluorinated alkanethiol or the like, the organic layer solution is applied thereto and dried, so the opening can be formed. In particular, the chemical modification treatment with partially fluorinated alkanethiol is desirable because a chemically stable and dense film is obtained, base material selectivity is high, and a patterning effect is large. In this case, the surface of the drain electrode is made of, for example, gold or palladium. However, the present invention is not limited to this.

Examples of the treatment (2) include laser processing, mechanical processing, and focused ion beam processing. The laser processing is a technique which can be widely applied to other fields (including printed circuit board processing). Therefore, the light emitting apparatus can be manufactured at low cost.

### (c) Second Electrode (Upper Electrode)

A metal or a metal oxide which has a sufficient electron injection characteristic (low work function) is used. It is necessary for the top emission type to provide sufficient transparency. To be specific, a vacuum deposited layer of magnesium-doped silver or a vacuum deposited bilayer of alkali metal salt and aluminum can be used.

### (d) TFT

A structure of the TFT will be described. The inverse staggered TFT is exemplified in the above description. Any one of a staggered TFT, an inverse staggered TFT, a coplaner TFT, and an inverse coplaner TFT can be employed.

Next, the channel layer will be described.

An n-type semiconductor film is used and formed by any one of a dry film formation method such as a sputtering method or an electron beam vapor deposition method and a wet film formation method such as a sol-gel method or a printing method. A field effect mobility larger than 1 cm²V⁻¹s⁻¹ is required. Oxide semiconductor can be used as a material satisfying this reference value. In other words, the channel layer contains at least one element selected from the group consisting of In, Ga, and Zn. An In—Ga—Zn—O thin film can be used as an amorphous film. A ZnO or In—Zn—O mixed crystal thin film can be used as a polycrystalline film. In particular, when an In—Ga—Zn—O sputtering film is used, at least the channel layer is transparent in visible light region and the TFT whose field effect mobility is large can be produced. The film can be formed by sputtering using a channel material, so a large-area light emitting apparatus can be manufactured. A film formation temperature for the channel material is low, so the light emitting apparatus can be manufactured on a flexible substrate such as a plastic substrate. At least a part of the In—Ga—Zn—O sputtering film is desirably made amorphous. Therefore, etching processability is improved. When the entire sputtering film is amorphous, a deviation in characteristics of adjacent pixel circuits which may be observed in the case of low-temperature poly-silicon TFTs can be prevented.

According to a method of measuring the field effect mobility of the TFT, there are some definitions. For example, the field effect mobility in the saturation region can be obtained as follows. The square root of a drain-source current (IDS) is plotted with respect to a gate-source voltage (VGS) and a tangent line is drawn at a gate voltage when the gradient of the plot is maximum, so the field effect mobility and a threshold voltage can be obtained based on the intercept and the slope of the tangent line (√Ids-Vgs method).

Next, the gate electrode, the source electrode, the drain electrode, and the line will be described.

For example, a metal such as Al, Cr, or W, an Al alloy, or a silicide such as WSi can be used for the gate electrode, the source electrode, the drain electrode, and the lines such as a power supply line, a selection line, and a data line. A single line may include multiple materials connected with each other. The line may be a multilayer film. When the drain electrode is subjected to surface modification in the case where the organic film is to be patterned, it is necessary to suitably select an electrode material. For example, when surface modification with thiol is performed, at least the uppermost surface of the drain electrode is desirably made of gold or palladium.

Next, the gate insulator will be described.

It is necessary to use a material which is capable of forming a flat film and has a gate-source leak current Igs which is practically sufficiently smaller than the drain-source current Ids. The gate insulator is selected from an Si₃N₄ film, an SiO₂ film, and an SiOₓN_{y} film, each of which is formed by chemical vapor deposition (CVD), an SiO₂ film formed by RF magnetron sputtering, and a multilayer film of those. The film formation using the CVD is desirable because a film deposition rate is large and a manufacturing time can be shortened. The film formation using the RF magnetron sputtering is desirable because a dense and thermally and chemically stable film is obtained and the environmental stability of the TFT is high.

Next, the channel protecting layer will be described.

The channel protecting layer is provided to protect the channel layer from chemical solutions used in subsequent processes performed after the formation of the TFT and from an atmosphere in use environment. The channel protecting layer is required to be capable of being patterned by a suitable method so as to expose at least a part of the drain electrode of the TFT. The channel protecting layer to be used is selected from the same material group as the gate insulator.

Hereinafter, examples of the present invention will be described. The present invention is not limited to the examples described below.

### Example 1

In this example, the light emitting apparatus according to the present invention was manufactured and evaluated.

An amorphous In—Ga—Zn—O sputtering film used as the channel layer of the TFT was evaluated.

A glass substrate (“Corning 1737” manufactured by Corning Incorporated) which was degreased and cleaned was prepared as a substrate to which films will be formed. A target material to be used was a polycrystalline sintered body (size: 98 mmΦ and 5 mm(t)) having an InGaO₃(ZnO) composition. The sintered body was produced as follow. Starting materials In₂O₃, Ga₂O₃, and ZnO (each of which is 4N reagent) was wet-mixed (solvent: ethanol), pre-sintered (at 1000° C. for two hours), dry-pulverized, and then sintered (at 1500° C. for two hours). An electrical conductivity of the target was 0.25 (Scm⁻¹) and thus the target was semi-insulating. The background pressure in a deposition chamber was 3×10⁻⁴ Pa. The total pressure during film formation was set to 0.53 Pa and an oxygen gas ratio was set to 3.3%. A substrate temperature was not particularly controlled. A distance between the target and the substrate to which the films were formed was 80 (mm). Input RF power was 300 W. A film formation rate was 2 (angstrom S⁻¹).

An X-ray beam was made incident on the film having a thickness of 60 nm at an incident angle of 0.5 degrees relative to a surface to be measured to perform X-ray diffraction measurement (thin film method). As a result, a clear diffraction peak was not observed. Therefore, it was determined that the produced In—Ga—Zn—O thin film was amorphous.

According to a result obtained by X-ray fluorescence (XRF) analysis, a metal composition ratio In:Ga:Zn of the thin film was 1:0.9:0.6. In grazing incidence X-ray reflectivity (GIXR) measurement, a clear oscillation pattern called Kiessig fringes was observed in a wide range of 2θ, so high smoothness of the film was suggested. The measured electrical conductivity of the thin film was approximately 7×10⁻⁵ (Scm⁻¹). When the obtained thin film was observed with white light, color visible to the naked eye was not given.

Therefore, it was apparent that the produced In—Ga—Zn—O thin film was an amorphous layer whose composition was similar to a composition of crystal of InGaO₃(ZnO)_{0.6} and was a transparent flat thin film whose oxygen defect is small and electrical conductivity is low.

Next, an inverse staggered TFT was produced according to the following procedure.

A glass substrate (“Corning 1737” manufactured by Corning Incorporated) was subjected to ultrasonic degreasing and cleaning for five minutes with each of acetone, IPA, and extrapure water, and then dried in the air at 100° C. A titanium film and a gold film were formed for the gate electrode on the substrate at a total thickness of 50 nm by an electron beam vapor deposition method and patterned by a lift-off method. Next, an SiO₂ layer serving as the gate insulator was formed on the entire surface by RF magnetron sputtering (film formation gas was Ar, film formation pressure was 0.1 Pa, input power was 400 W, and film thickness was 100 nm) and then patterned by etching. Subsequently, an amorphous IGZO layer serving as the channel layer was formed by RF magnetron sputtering (film formation gas was O₂ (3.3%)+Ar, film formation pressure was 0.53 Pa, input power was 300 W, and film thickness was 50 nm). Then, the channel layer was patterned by etching. During the sputtering film formation, the substrate temperature was not particularly controlled. Finally, a titanium film and a gold film were formed again for the source electrode and the drain electrode at a total thickness of 200 nm by an electron beam vapor deposition method. A channel length L and a channel width W were set to 10 (μm) and 40 (μm), respectively.

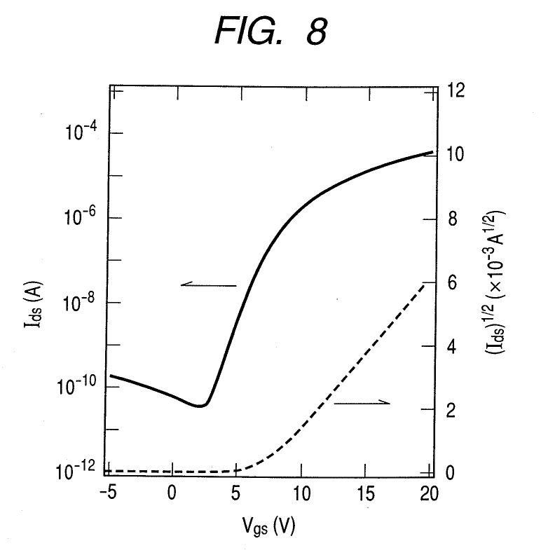

FIG. 8 illustrates an Ids-Vgs characteristic of the TFT produced according to the above-mentioned procedure, which was obtained by measurement at room temperature. A drain-source voltage (Vds) was set to +10 (V). When an on-off ratio was defined as a ratio of Ids at Vgs=+20 (V) to Ids at Vgs=0 (V), 6.5×10⁵ was obtained. A field effect mobility and a threshold voltage which was obtained by the √Ids-Vgs method were 3.5 (cm²V⁻¹s⁻¹) and +7.2 (V), respectively.

As is apparent from the description, the channel layer is made of n-type semiconductor. This does not contradict the fact that the amorphous In—Ga—Zn—O semiconductor is of the n-type. The field effect mobility of the TFT is sufficiently large, so high definition of pixels can be realized in a light emitting apparatus structure.

Next, the light emitting apparatus was manufactured.

An OLED was produced according to the following procedure on the glass substrate on which the TFT was formed in advance by the same method as described above. Therefore, the TFT and the OLED could be integrated. L was 5 (μm) and W was 690 (μm). A driving TFT area which did not include the area for the lines was limited to 0.02 mm² or less.

An SiO₂ layer serving as the TFT protecting layer was formed by RF magnetron sputtering and then patterned by etching. An ITO electrode serving as the anode of the OLED was formed to a region adjacent to the TFT located on the substrate by RF magnetron sputtering and then patterned by etching. Therefore, the bottom surface of the TFT and the bottom surface of the light emitting element were equal in height to each other.

The emission layer of the OLED was on the ITO electrode. The emission layer included a film of copper phthalosyanine (CuPc), a film of N, N′-di-1-naphthyl-N, N′-diphenyl-1, 1′-biphenyl-4, 4′-diamine (α-NPD), and a film of tris(8-hydroxyquinoline) aluminum (III) (Alq3), which were formed in the stated order by vacuum vapor deposition (resistance heating method). At this time, each layer was patterned using a shadow mask, in order to avoid forming any layer on a region of an upper surface of the drain electrode of the TFT, and to keep the region exposed. Finally, a cathode made of lithium fluoride and aluminum, of the OLED was formed by vacuum vapor deposition (resistance heating) using another shadow mask. The cathode extended to overlap with the exposed region of the drain electrode of the TFT. On completion of the film formation operation, the connection between the TFT and the OLED was completed. An effective area of the OLED is defined by a region in which the cathode overlaps with the anode and set to approximately 0.08 mm².

The anode of the OLED was connected with the power source and the source electrode of the TFT was grounded. When the signal voltage was applied to the gate electrode of the TFT, light modulated based on the applied voltage was emitted from the OLED.

According to the light emitting apparatus described above, the number of defective pixels caused by the faulty connection between the TFT and the light emitting element is small. A total area of the light emitting element and the TFT in each pixel is sufficiently small, so a high-definition light emitting apparatus can realized.

### Example 2

An OLED is produced according to the following procedure on the glass substrate on which the TFT is formed in advance by the same manner as Example 1. Therefore, the TFT and the OLED can be integrated.

An SiO₂ layer serving as the TFT protecting layer is formed by RF magnetron sputtering and then patterned by etching. Subsequently, an ITO electrode serving as the anode of the OLED is formed to a region adjacent to the TFT located on the substrate by RF magnetron sputtering and then patterned by etching. Subsequently, the bank made of photosensitive polyimide is formed for pixel separation of the emission layers. The bank is formed to expose both the TFT and the anode of the light emitting element (OLED). A thickness of the bank is set to a value equal to or larger than 1 μm. The ITO electrode is subjected to hydrophilic treatment such as oxygen plasma treatment. The bank is subjected to water repellent treatment such as fluorine plasma treatment. Subsequently, hydrophobic treatment is performed as follows. The resultant substrate is immersed into a toluene solution of partially fluorinated alkanethiol, CF₂(CF₂)₉(CH₂)₆SH, to be sufficiently rinsed with toluene, and then dried well. According to the operation, partially fluorinated alkanethiol is deposited to only the exposed region of the drain electrode to provide, with liquid repellency, a solution of the emission layer applied in a subsequent process.

In order to form the hole injecting layer and the emission layer, an aqueous solution of poly(3,4-ethylenedioxythiophene)-poly(styrenesulfonate) (PEDOT:PSS) and a solution of LUMATION Green 1303 (manufactured by The Dow Chemical Company) are applied in the stated order, respectively. The resultant substrate is dried in an inert atmosphere. At this time, a region of the drain electrode is exposed without forming the emission layer thereon.

Finally, the cathode made of lithium fluoride and aluminum, of the OLED is formed by vacuum vapor deposition (resistance heating) using a shadow mask. The effective area of the OLED is defined by a region in which the cathode overlaps with the anode and set to approximately 0.08 mm². The cathode extends to overlap with the exposed region of the drain electrode of the TFT. On completion of the film formation operation, the connection between the TFT and the OLED is completed.

The anode of the OLED is connected with the power source and the source electrode of the TFT is grounded. When the signal voltage is applied to the gate electrode of the TFT, light modulated based on the applied voltage is emitted from the OLED.

According to the light emitting apparatus described above, the number of defective pixels caused by the faulty connection between the TFT and the light emitting element is small. A total area of the light emitting element and the TFT in each pixel is sufficiently small, so a high-definition light emitting apparatus can realized. The emission layers can be formed from solution without being mixed with each other between adjacent pixels because the bank is formed. The method of providing the region on which the emission layer is not formed is realized by the hydrophobic treatment. Therefore, an alignment process for patterning the organic layer is unnecessary, so the light emitting apparatus can be manufactured at low cost. The hydrophobic treatment is the chemical modification treatment with partially fluorinated alkanethiol, so a hydrophobic coating film which is chemically stable and dense is obtained and the patterning effect is high.

### Example 3

An OLED is produced according to the following procedure on the glass substrate on which the TFT is formed in advance by the same manner as Example 1. Therefore, the TFT and the OLED can be integrated.

An SiO₂ layer serving as the TFT protecting layer is formed by RF magnetron sputtering and then patterned by etching. Subsequently, an ITO electrode serving as the anode of the OLED is formed to a region adjacent to the TFT located on the substrate by RF magnetron sputtering and then patterned by etching. Subsequently, the bank made of photosensitive polyimide is formed for pixel separation of the emission layers. The bank is provided to cover the channel region of the TFT and to expose a part of the drain electrode. A thickness of the bank is set to a value equal to or larger than 1 μm. The ITO electrode is subjected to hydrophilic treatment such as oxygen plasma treatment. The bank is subjected to water repellent treatment such as fluorine plasma treatment. In order to form the hole injecting layer and the emission layer, an aqueous solution of PEDOT:PSS and a solution of LUMATION Green 1303 (manufactured by The Dow Chemical Company) are applied in the stated order. The resultant substrate is dried in an inert atmosphere. At this time, the emission layer is formed on a region exposed to the outside of the bank, of the drain electrode of the TFT. The emission layer and the hole injecting layer which are located in a part of the exposed region are removed by ablation using a near-infrared laser processing machine whose power is suitably adjusted. Finally, the cathode of the OLED is formed by vacuum vapor deposition (resistance heating) using a shadow mask. The effective area of the OLED is defined by a region in which the cathode overlaps with the anode and set to approximately 0.08 mm². The cathode extends to overlap with the laser-processed part. On completion of the film formation operation, the connection between the TFT and the OLED is completed.

The anode of the OLED is connected with the power source and the source electrode of the TFT is grounded. When the signal voltage is applied to the gate electrode of the TFT, light modulated based on the applied voltage is emitted from the OLED.

According to the light emitting apparatus described above, the number of defective pixels caused by the faulty connection between the TFT and the light emitting element is small. A total area of the light emitting element and the TFT in each pixel is sufficiently small, so a high-definition light emitting apparatus can be realized. The channel region of the TFT is contained in the inner portion of the bank, so the aperture ratio can be increased. The method of providing the part on which the emission layer is not formed is realized by the laser ablation, so the light emitting apparatus can be manufactured at low cost.

### Example 4

An SiO₂ layer is formed by sputtering as in Example 3 and then an Si₃N₄ layer is formed by CVD (up to 3 μm in thickness). The two-layer film is collectively patterned to act as the “protecting layer for the channel region of the TFT” and the “bank for the emission layers”. The bank is provided to cover the channel region of the TFT and to expose at least a part of the drain electrode. Subsequently, an ITO electrode serving as the anode of the OLED is formed to a region adjacent to the TFT located on the substrate by RF magnetron sputtering and then patterned by etching. The ITO electrode is subjected to oxygen plasma treatment which is hydrophilic treatment. The process for forming the hole injecting layer and the emission layer and the subsequent processes are performed as in the case of Example 3.

The anode of the OLED is connected with the power source and the source electrode of the TFT is grounded. When the signal voltage is applied to the gate electrode of the TFT, light modulated based on the applied voltage is emitted from the OLED.

According to the light emitting apparatus described above, the number of defective pixels caused by the faulty connection between the TFT and the light emitting element is small. A total area of the light emitting element and the TFT in each pixel is sufficiently small, so a high-definition light emitting apparatus can be realized. The channel protecting layer of the TFT also acts as the bank. Therefore, the emission layer can be formed from solution and the aperture ratio can be increased.

The light emitting apparatus and the manufacturing method therefor according to the present invention are widely used for various flat panel displays represented by organic electric field light emitting displays. The point that the high-mobility n-type semiconductor is used to ensure an area of a device to be driven can be widely applied not only to a display device array using TFTs as switching devices but also to various sensor arrays using TFTs as switching devices and various actuator arrays using TFTs as switching devices. When an n-type semiconductor film which can be formed at room temperature is selected, the selected n-type semiconductor film can be formed on a low-melting-point substrate such as a plastic substrate. Therefore, the present invention can be applied to wide fields including an IC card and an IC tag.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-118737, filed Apr. 27, 2007, which is hereby incorporated by reference herein in its entirety.

1. A light emitting apparatus, comprising:
a substrate;
a light emitting element which includes a first electrode, an emission layer, and a second electrode which are stacked on the substrate in the stated order; and
a thin film transistor which is of an n-type and includes a channel layer and a drain electrode,
wherein:
the light emitting element and the thin film transistor are arranged in parallel and in contact with the substrate;
the channel layer of the thin film transistor has a field effect mobility equal to or larger than 1 cm²V⁻¹s⁻¹; and
the second electrode is connected with the drain electrode of the thin film transistor.

2. The light emitting apparatus according to claim 1, wherein:
the channel layer of the thin film transistor contains at least one element selected from the group consisting of In, Ga, and Zn; and
at least a part of the channel layer includes an amorphous oxide.

3. The light emitting apparatus according to claim 1, wherein the emission layer includes an organic compound.

4. The light emitting apparatus according to claim 1, wherein at least one of the first electrode and the second electrode includes a transparent conductive oxide.

5. The light emitting apparatus according to claim 1, further comprising an insulator inserted between the substrate and the first electrode.

6. The light emitting apparatus according to claim 5, wherein the insulator serves as a channel protecting layer.

7. The light emitting apparatus according to claim 5, wherein the insulator serves as a planarization layer for the first electrode.

8. The light emitting apparatus according to claim 1, further comprising a bank provided between pixels located adjacent to each other, for separating the emission layer.

9. The light emitting apparatus according to claim 8, wherein at least a part of a channel portion of the thin film transistor is formed in the bank.

10. The light emitting apparatus according to claim 8, further comprising a channel protecting layer,
wherein the channel protecting layer acts as the bank.

11. A method of manufacturing a light emitting apparatus, comprising:
forming, on a substrate, a thin film transistor which is of an n-type and includes a gate electrode, a line, a gate insulator, a channel layer, a source electrode, a drain electrode, and a channel protecting layer;
forming, on the substrate, a first electrode of a light emitting element in parallel with the thin film transistor;
stacking an emission layer on the first electrode;
stacking a second electrode on the emission layer and the drain electrode of the thin film transistor to connect the emission layer with the drain electrode; and
sealing a portion including at least the light emitting element on the substrate on which the light emitting element and the thin film transistor are formed,
wherein the stacking the emission layer on the first electrode is performed so as not to form the emission layer on at least a part of a surface of the drain electrode of the thin film transistor.

12. The method according to claim 11, further comprising performing hydrophobic treatment on at least the part of the surface of the drain electrode before the stacking the emission layer on the first electrode.

13. The method according to claim 12, wherein the hydrophobic treatment comprises chemical modification treatment with partially fluorinated alkanethiol, which is performed on the surface of the drain electrode.

14. The method according to claim 11, further comprising:
after the stacking the emission layer on the first electrode,
removing a part of the emission layer formed on the drain electrode.

15. The method according to claim 14, wherein the removing the part of the emission layer comprises treatment using laser ablation.
